(19) United States
(12) Patent Application Publication
(10) Pub. No.: US 2018/0135172 A1
(43) Pub. Date: May 17, 2018

(54) SUSCEPTOR, EPITAXIAL GROWTH DEVICE, AND EPITAXIAL WAFER

(71) Applicant: SUMCO CORPORATION, Tokyo (JP)

(72) Inventors: Shoji NOGAMI, Tokyo (JP); Naoyuki WADA, Tokyo (JP)

(73) Assignee: SUMCO CORPORATION, Tokyo (JP)

(21) Appl. No.: 15/567,159

(22) PCT Filed: Apr. 22, 2016
(86) PCT No.: PCT/JP2016/002165

§ 371 Date: Oct. 17, 2017

(30) Foreign Application Priority Data
Apr. 27, 2015 (JP) 2015-090563

(51) Int. Cl. C23C 16/458; C30B 25/12

(52) U.S. Cl. CPC C23C 16/4583; C30B 25/12

(57) ABSTRACT

Provided is a susceptor, capable of preventing occurrence of deep scratches on the back surface and beveled part of a wafer attributable to contact with lift pins or the susceptor, and reducing dust generation from the susceptor. A susceptor according to one embodiment of this disclosure includes a susceptor main body, and arc-shaped members. The bottom surface of a counterbore part is constituted of the entire front surfaces of the arc-shaped susceptor members, and a part of the front surface of the susceptor main body. When a wafer is conveyed, the entire front surfaces of the arc-shaped members ascended by lift pins support only the outer circumferential part of the back surface of the wafer by surface contact.

### TECHNICAL FIELD

This disclosure relates to a susceptor for placing a wafer thereon within an epitaxial wafer growth device, an epitaxial growth device having the susceptor, and an epitaxial wafer that can be produced by the epitaxial growth device.

### BACKGROUND

An epitaxial wafer is formed by growing an epitaxial film on the surface of a semiconductor wafer by vapor phase growth. For example, when crystal integrity is further required, when a multi-layer structure of different resistivity is needed, or the like, an epitaxial silicon wafer is produced by growing a single crystal silicon thin film on a silicon wafer by vapor phase growth or epitaxial growth.

For epitaxial wafer production, a single wafer type epitaxial growth device (apparatus) is used for example. Here, a typical single wafer type epitaxial growth device will be described with reference to FIG. 8. As illustrated in FIG. 8, an epitaxial growth device 200 has a chamber 10 including an upper dome 11, a lower dome 12, and a dome mounting body 13, and the chamber 10 defines an epitaxial film forming chamber. The chamber 10 is provided with a gas supply opening 15 and a gas exhaust opening 16 for supplying and exhausting a reaction gas at opposing positions on the side surface thereof. Meanwhile, a susceptor 20 for placing a wafer W thereon is arranged within the chamber 10. The susceptor 20 is supported by a susceptor support shaft 50 from below. The susceptor support shaft 50 includes a main column 52, and three arms 54, including one not illustrated, radially extending from this main column 52 with an equal distance between them. Three supporting pins 58, including one not illustrated, at the tip of the arms are fitted to and support the outer circumferential part of the back surface of the susceptor 20. Moreover, three penetration holes, including one not illustrated, are formed in the susceptor 20, and a penetration hole is also formed in each of the three arms 54. Lift pins 44 are inserted through these penetration holes of the arms and the susceptor. The lower end of the lift pins 44 is supported by an ascending/descending shaft 60. When the wafer W carried into the chamber 10 is being supported, when this wafer W is being placed on the susceptor 20, and when the epitaxial wafer after vapor phase growth is carried out of the chamber 10, by the ascending/descending shaft 60 ascending and descending, the lift pins 44 ascend and descend while sliding with the penetration holes of the arms and the penetration holes of the susceptor, and ascend and descend the wafer W at the upper end thereof.

In such an epitaxial growth device, the wafer W is directly supported and lifted by the lift pins. Therefore, to a part of the back surface of the wafer W abutting against the lift pins, the lift pins ascend and abut, and contact with the upper end of the lift pins is continuously maintained. Thus, there has been a problem that scratches or pin marks having a depth more than 0.5 μm occur in the above mentioned part of the back surface of the wafer W.

Moreover, JP 2001-313329 A (PTL 1) discloses the technique of lifting a wafer directly by a part of a susceptor, instead of supporting and lifting the wafer directly by lift pins. More specifically, FIG. 2 and FIG. 3 of PTL 1 describe relatively lifting a soft ring 32 accommodated in a recessed part provided in the periphery of a susceptor main body 22 from the susceptor main body 22 by lift pins 48, and supporting an edge part of the wafer by three lift members 36 protruding inside from the soft ring 32.

### CITATION LIST

### Patent Literature

PTL 1: JP 2001-313329 A

### SUMMARY

### Technical Problem

According to the technique of PTL 1, since the wafer is, when lifted, supported by a part of the susceptor at an edge part of the wafer, without being locally supported by lift pins, occurrence of scratches on the back surface of the wafer attributable to lift pins can be prevented. However, since a beveled part or edge part of the wafer is supported by point contact using three lift members 36, i.e., projections protruding inside from the soft ring 32, it is concerned that scratches having a depth more than 0.5 μm occur on the beveled part of the wafer. Additionally, the inventors have newly recognized that the technique of PTL 1 has a problem as follows.

More specifically, in PTL 1, the recessed part for accommodating the soft ring therein is located in the periphery of the susceptor main body, and outside the edge of the wafer. Therefore, at the time of vapor phase growth, the front surface of the soft ring and the front surface of the susceptor main body around the recessed part are in contact with a source gas to grow an epitaxial film, and the epitaxial film may even connect at a horizontal separation part between the soft ring and the susceptor main body. Thereafter, when the soft ring is relatively lifted from the susceptor main body, the epitaxial film connected at the separation part breaks and generates dust. It is desirable to reduce this dust, which attaches to the surface of the produced epitaxial wafer and generates many defects.

Therefore, in consideration of the above problems, this disclosure has the purpose of providing a susceptor and an epitaxial growth device, capable of preventing occurrence of deep scratches on the back surface and beveled part of a wafer attributable to contact with lift pins or the susceptor and reducing dust generation from the susceptor. Moreover, this disclosure has the purpose of providing an epitaxial wafer that has no observed scratches having a depth more than 0.5 μm which can occur due to contact with the lift pins or the susceptor.

### Solution to Problem

The brief configuration of this disclosure for solving the above problems is as follows.

1. A susceptor for placing a wafer thereon within an epitaxial growth device, wherein

a counterbore part for placing the wafer thereon is formed on a front surface of the susceptor,

the susceptor has a susceptor main body, and two or more arc-shaped members placed on two or more recessed parts provided in an outer circumferential part of a front surface of the susceptor main body,

a bottom surface of the counterbore part is constituted of entire front surfaces of the arc-shaped members, and a part of the front surface of the susceptor main body,

the susceptor main body is provided with two or more penetration holes, for lift pins that support a back surface of the two or more arc-shaped members, and ascend and descend the two or more arc-shaped members, to be inserted therethrough, and

when the wafer is being placed on the counterbore part and when the wafer is carried out of the counterbore part, the entire front surfaces of the arc-shaped members ascended by the lift pins act as a supporting surface for supporting only an outer circumferential part of a back surface of the wafer by surface contact.

2. The susceptor according to the above item 1, the number of the arc-shaped members is two, located in substantially line symmetry from a front view.

3. The susceptor according to the above item 1 or 2, wherein the lift pins are fixed to the arc-shaped members.

4. An epitaxial growth device comprising: the susceptor according to any one of the above items 1 to 3; and an ascending/descending mechanism for ascending and descending the lift pins by supporting a lower end of the lift pins.

5. An epitaxial wafer comprising: a wafer; and an epitaxial layer formed on a surface of the wafer, wherein scratches having a depth more than 0.5 μm are not observed when a back surface and a beveled part of the epitaxial wafer are observed using a laser microscope.

6. The epitaxial wafer according to the above item 5, wherein scratches having a depth as small as 0.3 μm or less are not observed when a central part of the back surface of the epitaxial wafer is observed using a laser microscope.

### Advantageous Effect

The susceptor and the epitaxial growth device according to this disclosure can prevent occurrence of deep scratches on the back surface and beveled part of a wafer attributable to contact with the lift pins or the susceptor and reduce dust generation from the susceptor. Moreover, by using this susceptor and epitaxial growth device, an epitaxial wafer that has no observed scratches having a depth more than 0.5 μm which can occur due to contact with the lift pins or the susceptor.

### BRIEF DESCRIPTION OF THE DRAWINGS

This disclosure will be further described with reference to the accompanying drawings, in which:

FIGS. 1A, 1B and 1C are schematic section views of the susceptor 20 according to one embodiment of this disclosure, where FIG. 1A illustrates a state of having no wafer placed thereon (a I-I section view of FIG. 2C), FIG. 1B illustrates a state of having the wafer W placed on the counterbore part 21 of FIG. 1A, and FIG. 1C illustrates a state of having the wafer W lifted by arc-shaped members 40A and 40B;

FIG. 2A is a top view of a susceptor main body 30 in the susceptor 20 of FIG. 1, FIG. 2B is a top view of the arc-shaped members 40A and 40B in the susceptor 20 of FIG. 1, and FIG. 2C is a top view of the susceptor 20 in a state of having the arc-shaped members 40A and 40B on the recessed part of the susceptor main body 30;

FIG. 3 is an enlarged section view of FIG. 1C;

FIG. 4 is a section view of a susceptor according to Comparative Example similar to FIG. 3;

FIG. 5A is an exploded perspective view of the susceptor support shaft 50, and FIG. 5B is an exploded perspective view of the ascending/descending shaft 60;

FIG. 6 is a schematic view of an epitaxial growth device 100 according to one embodiment of this disclosure, illustrating a state of having the wafer W placed on the susceptor, at the time of vapor phase growth;

FIG. 7 is a schematic view of the epitaxial growth device 100 according to one embodiment of this disclosure, illustrating a state of having the wafer W lifted by the arc-shaped members 40A and 40B;

FIG. 8 is a schematic view of the conventional epitaxial growth device 200, illustrating a state of having the lift pins 40 descended with respect to the susceptor 20, at the time of vapor phase growth; and

FIG. 9A is an image of the back surface of an epitaxial silicon wafer observed using a laser microscope in Conventional Example, and FIG. 9B is the image in Example.

### DETAILED DESCRIPTION

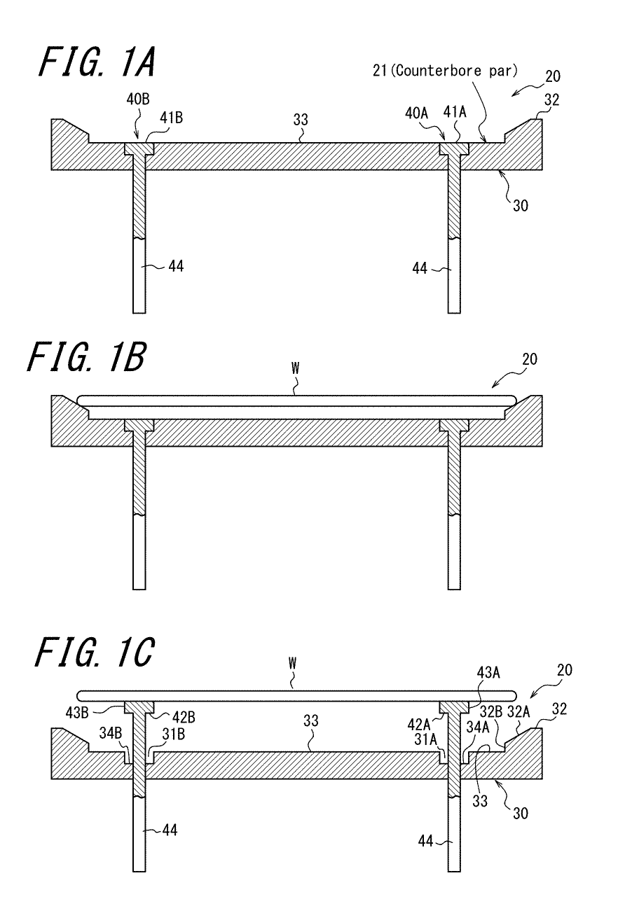

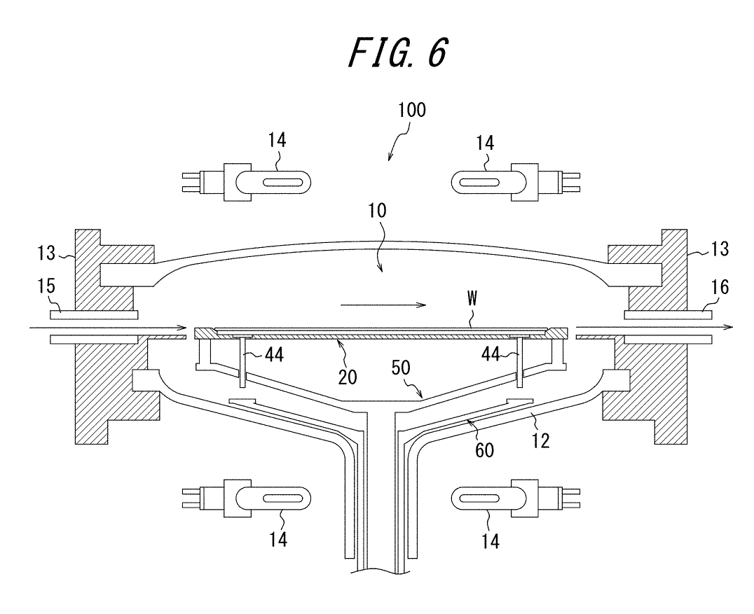

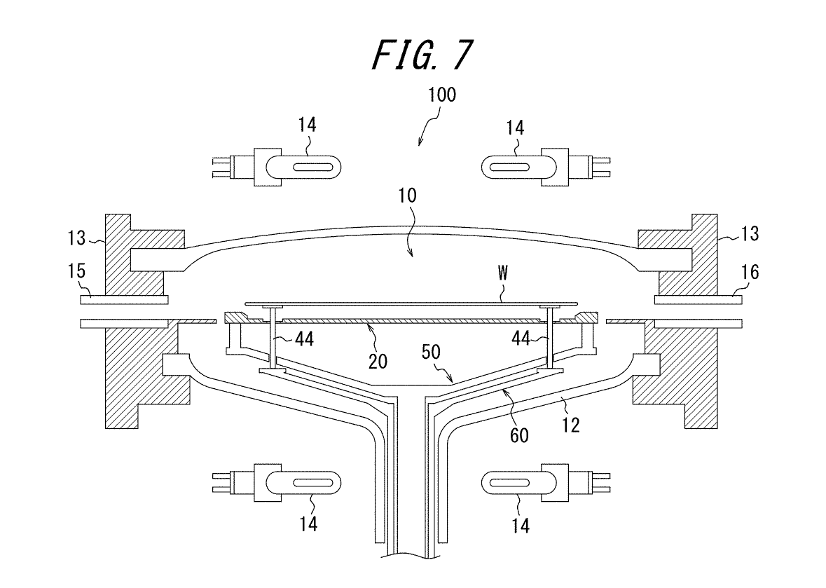

With reference to FIG. 6 and FIG. 7, the epitaxial growth device 100 according to one embodiment of this disclosure will be described. Moreover, with reference to FIGS. 1 to 3, the susceptor 20 according to one embodiment of this disclosure, which is included in this epitaxial growth device 100, will be described.

Epitaxial Growth Device

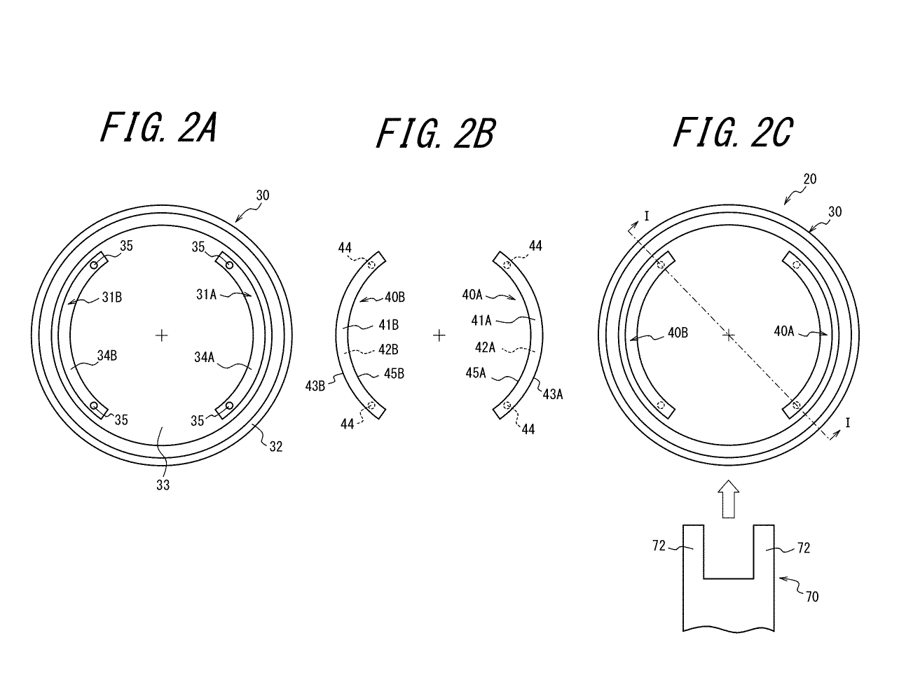

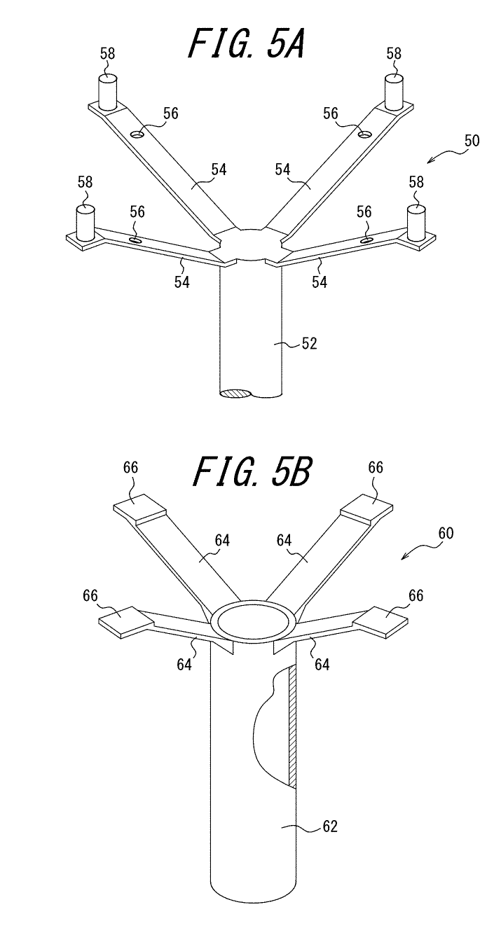

The epitaxial growth device 100 illustrated in FIG, 6 and FIG. 7 has the chamber 10, a heat lamp 14, the susceptor 20 also illustrated in FIG. 1 and FIG. 2, the susceptor support shaft 50 also illustrated in FIG. 5A, and the ascending/descending shaft 60 also illustrated in FIG. 5B.

Chamber

The chamber 10 includes the upper dome 11, the lower dome 12 and the dome mounting body 13, and this chamber 10 defines the epitaxial film forming chamber. The chamber 10 is provided with the gas supply opening 15 and the gas exhaust opening 16 for supplying and exhausting a reaction gas at opposing positions on the side surface thereof.

Heat Lamp

The heat lamp 14 is arranged in the upper side region and the lower side region of the chamber 10, and generally a halogen lamp or infrared lamp having a high temperature increase/decrease rate, and excellent temperature controllability is used.

Main Configuration of Susceptor

With reference to FIG. 1 and FIG. 2, the main configuration of the susceptor 20 will be described. The susceptor 20 is a disc-shaped member for placing the wafer W thereon inside the chamber 10. For the susceptor 20, carbon graphite or graphite as a base material having the surface thereof coated with silicon carbide can be used. With reference to FIGS. 1A and 1B, the counterbore part 21 for placing the wafer W thereon is formed in the front surface of the susceptor 20. The diameter of the counterbore part 21 at the opening end may be set accordingly in consideration of the diameter of the wafer W, and normally is about 1.0 to 2.0 mm larger than the diameter of the wafer W.

With reference to FIGS. 1A to 1C, the susceptor 20 has the susceptor main body 30, and the two arc-shaped members 40A and 40B respectively placed on two recessed parts 31A and 31B provided in the outer circumferential part of the front surface of this susceptor main body.

With reference to FIGS. 1A to 1C and FIG. 2A, the front surface of the susceptor main body 30 includes a front surface outer circumferential part 32, a wafer supporting surface 32A, a vertical wall surface 32B, a front surface central part 33, and surfaces of recessed parts 31A and 319, including bottom surfaces 34A and 34B. The front surface outer circumferential part 32 is located around the counterbore part 21 illustrated in FIG. 1A. The wafer supporting surface 32A is an inclined surface located inside the front surface outer circumferential part 32, supporting the back surface periphery of the wafer W by line contact, and constituting a part of the counterbore part. The vertical wall surface 32B is a wall surface continuous from the inner circumferential end of the wafer supporting surface 32A, and constituting a part of the counterbore part. The front surface central part 33 is continuous from the vertical wall surface 32B, and constitutes a part of the bottom surface of the counterbore part 21. The recessed parts 31A and 31B have the same shape as the arc-shaped members 40A and 40B from the front surface perspective of FIG. 2A, for accommodating and placing the arc-shaped members 40A and 40B. The dimension of the recessed parts 31A and 31B is set so that a gap or clearance between the arc-shaped members 40A and 40B, and the susceptor main body 30 becomes a necessary minimum, e.g., about 0.1 to 1.0 mm. The susceptor main body 30 is provided with four penetration holes 35 penetrating the bottom surfaces 34A and 34B, and the back surface in the vertical direction. The lift pins 44 described below are inserted through the four penetration holes 35.

With reference to FIGS. 1A to 1C and FIG. 2B, the arc-shaped members 40A and 40B are arc-shaped members from a top view, which respectively have front surfaces 41A and 41B, and back surfaces 42A and 42B, and are respectively placed on the recessed parts 31A and 31B with the necessary minimum gap or clearance. As illustrated in FIG. 1A, the front surfaces 41A and 41B constitute a part of the bottom surface of the counterbore part 21, and the back surfaces 42A and 42B are respectively in contact with and supported by the bottom surfaces 34A and 34B of the recessed parts. From the perspective of stably supporting the wafer W, the outer circumferential surfaces 43A and 43B, and the inner circumferential surfaces 45A and 45B of the arc-shaped members are preferable to have the same curvature from a front view, and their curvature is preferable to be about 80 to 120% of the wafer curvature, and more preferable to be 100%. Moreover, from the perspective of stably supporting the wafer W, the two arc-shaped members 40A and 40B are preferably located in substantially line symmetry as illustrated in FIG. 2C.

Two lift pins 44 extend from each of the back surfaces 42A and 42B. These four lift pins 44 in total are respectively inserted through the four penetration holes 35 provided in the susceptor main body. The lift pins 44 can attach and detach the arc-shaped members 40A and 40B, and the susceptor main body 30, while supporting the back surfaces 42A and 42B of the arc-shaped members, by being ascended and descended in the vertical direction by the ascending/descending shaft 60 described below. This motion will be described below. From the perspective of stably ascending and descending the arc-shaped members, it is preferable to provide each arc-shaped member with two lift pins, and to provide these two lift pins in the vicinity of both ends of the arc-shaped member. Although the lift pins 44 are fixed to the arc-shaped members 40A and 40B in this embodiment, the lift pins 44 may not be fixed to the arc-shaped members 40A and 40B.

As illustrated in FIGS. 1A and 1B, the bottom surface of the counterbore part 21 is constituted of the entire front surfaces 41A and 41B of the arc-shaped members, and a part of the front surface of the susceptor main body, specifically the front surface central part 33. More specifically, in a state in which the arc-shaped members 40A and 40B are respectively placed on the recessed parts 31A and 31B, and the wafer W is placed on the counterbore part 21, among the surfaces of the counterbore part 21, the entire front surfaces 41A and 41B of the arc-shaped members, and the front surface central part 33 of the susceptor main body are separate from and opposite to the back surface of the wafer W.

Meanwhile, as illustrated in FIG. 1C, when the wafer W is being placed on the counterbore part 21, and when the wafer W is carried out of the counterbore part 21, i.e., the wafer W is conveyed, the susceptor main body 30, and the arc-shaped members 40A and 40B are separate in the vertical direction, and the entire front surfaces 41A and 41B of the arc-shaped members ascended by the lift pins 44 act as supporting surfaces for supporting only the outer circumferential part of the back surface of the wafer W by surface contact. Therefore, occurrence of deep scratches on the back surface and beveled part (chamfer part) of the wafer W attributable to contact with the lift pins or the susceptor can be prevented. Specifically, according to this disclosure, when the back surface and beveled part of the produced epitaxial wafer are observed using a laser microscope, scratches having a depth more than 0.5 μm are not observed. Here in the specification, “the outer circumferential part of the back surface of the wafer” means a region separate from the wafer center by not less than 70% of the wafer radius in the back surface of the wafer.

Moreover, in the specification, “the central part of the back surface of the wafer” means a region inside the outer circumferential part of the back surface of the wafer, i.e., a region within less than 70% of the wafer radius from the wafer center. Furthermore, in this embodiment, since the arc-shaped members 40A and 40B support only the outer circumferential part of the back surface of the wafer W, the central part of the back surface does not have contact, not only point contact but also surface contact, with any members. Therefore, when the central part of the back surface of the produced epitaxial wafer is observed using a laser microscope, even scratches or contact scratches having a depth as small as 0.3 μm or less are not observed. During the epitaxial growth treatment, a phenomenon such as warp projecting upward or downward occurs in the wafer W under a high temperature heat treatment. Thus, if contact scratches are present on the back surface central part of the wafer W, slip dislocation is more likely to occur from these scratches as a starting point, which is not a concern in this embodiment.

The wafer W supported by the arc-shaped members 40A and 40B are conveyed out of the chamber, while the back surface central part of the wafer W is supported by a wafer supporting part 72 of a U-shaped conveying blade 70 inserted from the direction illustrated in FIG. 2C. The arc-shaped members 40A and 40B are arranged not to interfere with the wafer supporting part 72 of the conveying blade.

The surface part of the arc-shaped members 40A and 40B or the entirety of the arc-shaped members 40A and 40B is preferably made of a soft material such as glassy carbon. It is because occurrence of scratches when the back surface of the wafer W is supported by surface contact can be prevented.

In addition, the bottom of the recessed parts 31A and 31B of the susceptor main body, and the arc-shaped members 40A and 40B are also preferably porous structures. It is because by promoting hydrogen gas to sneak into the back surface of the wafer W, occurrence of halo or haze on the wafer back surface can be prevented.

Susceptor Support Shaft

With reference to FIG. 5A, the susceptor support shaft 50 supports the susceptor 20 from below within the chamber 10, and has the main column 52, the four arms 54, and the four supporting pins 58. The main column 52 is arranged on substantially the same axis as the center of the susceptor. The four arms 54 radially extend below the periphery of the susceptor 20 from the main column 52, and respectively have penetration holes 56 penetrating in the vertical direction. Additionally in the specification, “the periphery of the susceptor” means a region outside the susceptor center by not less than 80% of the susceptor radius. The supporting pins 58 are respectively provided in the tip of the four arms 54, and directly support the susceptor 20. More specifically, the supporting pins 58 support the back surface periphery of the susceptor. The four lift pins 44 are respectively inserted through the four penetration holes 56. The susceptor support shaft 50 is desirable to be constituted of quartz, and is desirable to be constituted particularly of synthetic quartz. However, the tip part of the supporting pins 58 is preferable to be constituted of silicon carbide, which is the same as the susceptor 20.

Ascending/Descending Shaft

As illustrated in FIG. 5B, the ascending/descending shaft 60 as an ascending/descending mechanism has a main column 62 defining a hollow for accommodating the main column 52 of the susceptor support shaft and having a shared rotation axis with this main column 52, and four support columns 64 branching from the tip of this main column 62. The tip parts 66 of these support columns 64 supports the lower end of the lift pins 44 respectively. The ascending/descending shaft 60 is preferably constituted of quartz. By the ascending/descending shaft 60 moving up and down along the main column 52 of the susceptor support shaft in the vertical direction, the lift pins 44 can be ascended and descended.

Production Procedure for Epitaxial Wafer

Next, a series of actions of carrying the wafer W into the chamber 10, vapor phase growth of an epitaxial film onto the wafer W, and carrying the produced epitaxial wafer out of the chamber 10 will be described with appropriate reference to FIG. 6 and FIG. 7.

The wafer W carried into the chamber 10 while being supported by the conveying blade 70 illustrated in FIG. 2C is temporarily placed on the front surfaces 41A and 41B of the arc-shaped members 40A and 40B lifted by the lift pins 44. The ascending movement of the lift pins 44 is performed through the ascending movement of the ascending/descending shaft 60 supporting their lower end.

Then, by ascending the susceptor support shaft 50, the susceptor main body 30 is moved to a position of the arc-shaped members 40A and 40B, and the wafer W is placed on the counterbore part 21 of the susceptor 20. Subsequently, an epitaxial wafer is produced by, while heating the wafer W to a temperature not lower than 1000° C. by the heat lamp 14, supplying a reaction gas from the gas supply opening 15 into the chamber 10, and growing an epitaxial film having a predetermined thickness by vapor phase growth. During vapor phase growth, by rotating the susceptor support shaft 50 using the main column 52 as a rotation axis, the susceptor 20 and the wafer W thereon are rotated.

Thereafter, by descending the susceptor support shaft 50, the susceptor main body 30 is descended. This descending is performed until the lift pins 44 are supported by the ascending/descending shaft 60 and the arc-shaped members 40A and 40B are separate from the susceptor main body 30, and the produced epitaxial wafer is supported by the front surfaces 41A and 41B of the arc-shaped members 40A and 40B supported by the lift pins 44. Then, the conveying blade 70 is introduced into the chamber 10, and the epitaxial wafer is placed on the wafer supporting part 72 of the conveying blade by descending the lift pins 44. Thus, the epitaxial wafer is passed from the arc-shaped members 40A and 40B to the conveying blade 70. Subsequently, the epitaxial wafer is carried out of the chamber 10 along with the conveying blade 70.

Configuration of Characteristic Part of Susceptor

Here, the position of the arc-shaped members 40A and 40B, as a characteristic configuration of this disclosure, will be described in detail.

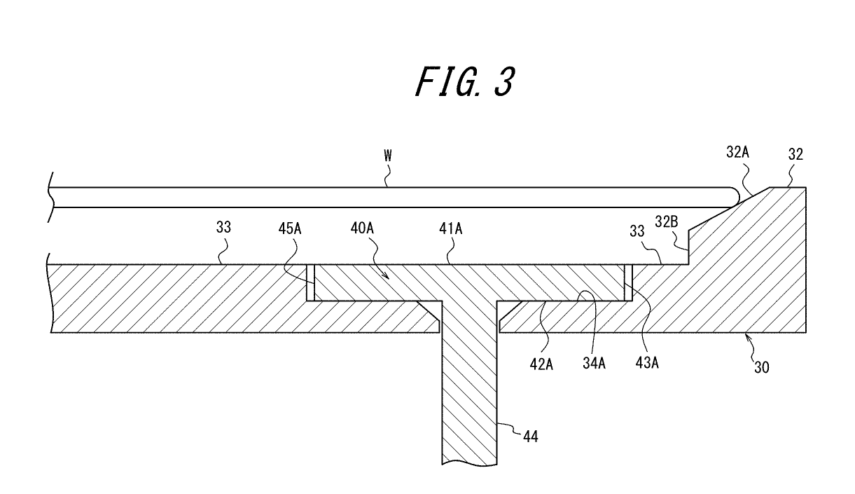

With reference to FIG. 3, in the susceptor 20 of this embodiment, the entire front surfaces 41A and 41B of the arc-shaped members are opposing to the back surface of the wafer W. More specifically, together with reference to FIG. 2C, the entire recessed parts 31A and 31B, and the entire arc-shaped members 40A and 40B are located immediately below the outer circumferential part of the wafer W and inside the edge part of the wafer.

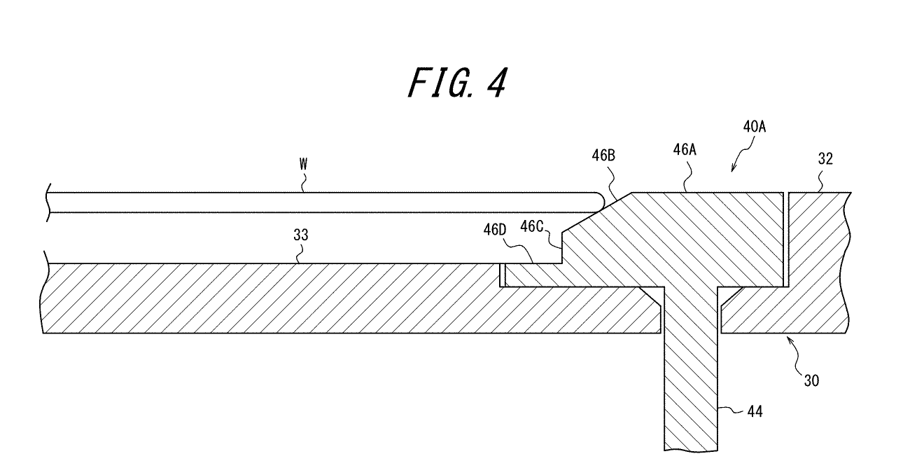

The technical significance of adopting such a configuration will be described with comparison to FIG. 4 illustrating Comparative Example which is not Conventional Example. In FIG. 4, the front surface of the arc-shaped member 40A is composed of a horizontal surface 46A located around the counterbore part 21, a wafer supporting surface 46B located inside this horizontal surface 46A and supporting the back surface periphery of the wafer W by line contact, a vertical wall surface 46C continuous from the inner circumferential end of this wafer supporting surface 46B, and a horizontal surface 46D continuous from this vertical wall surface 46C and constituting a part of the bottom surface of the counterbore part 21. In other words, the arc-shaped member 40A is located in the periphery of the susceptor main body 30, and extends further outside the edge part of the wafer W. Therefore, at the time of vapor phase growth, even the horizontal surface 46A and the front surface outer circumferential part 32 of the susceptor main body are in contact with a source gas to grow an epitaxial film, and the epitaxial film may even connect at the horizontal separation part between the horizontal surface 46A and the front surface outer circumferential part 32. Thereafter, when the arc-shaped member 40A is relatively lifted from the susceptor main body 30, the epitaxial film connected at the separation part breaks and generates dust. This dust attaches to the surface of the produced epitaxial wafer and generates many defects.

Contrarily, in this embodiment illustrated in FIG. 3, the entire arc-shaped members 40A and 40B are located immediately below the outer circumferential part of the wafer W and inside the edge part of the wafer. Therefore, an epitaxial film does not grow at the horizontal separation part between the arc-shaped members 40A and 40B, and the susceptor main body 30, and as a result, dust attributable to this epitaxial film is not generated.

### EXAMPLES

### Example

Using the susceptor illustrated in FIGS. 1 to 3 and the epitaxial growth device illustrated in FIGS. 6 and 7, an epitaxial silicon wafer was produced by following the procedure described above. In FIG. 3, the clearance between the edge of the wafer and the end of the counterbore part was 1.25 mm, a horizontal distance between the outside end of the recessed part and the edge of the wafer was 2.25 mm. As a substrate for the epitaxial wafer, a boron doped silicon wafer having a diameter of 300 mm was used.

### Comparative Example

Similarly to Example except for using the susceptor illustrated in FIG. 4, an epitaxial silicon wafer was produced.

### Conventional Example

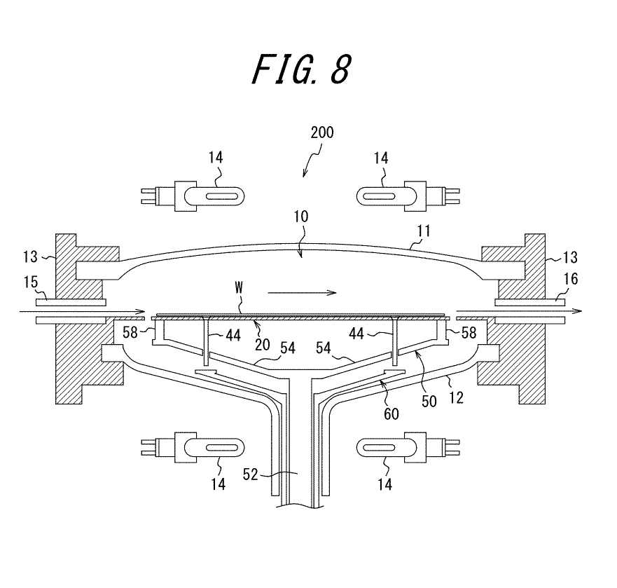

Using the conventional epitaxial growth device illustrated in FIG. 8, an epitaxial silicon wafer was produced.

[Vapor Phase Growth Conditions]

For producing epitaxial wafers, a silicon wafer was introduced into the chamber, and placed on the susceptor in the previously described method. Then, a hydrogen bake out was performed under a hydrogen gas atmosphere at 1150° C., and a silicon epitaxial film was grown on the silicon wafer surface by 4 μm at 1150° C., to obtain an epitaxial silicon wafer. Here, trichlorosilane gas was used as a raw material source gas, diborane gas as a dopant gas, and hydrogen gas as a carrier gas. Subsequently, by the previously described method, the epitaxial silicon wafer was carried out of the chamber.

[Evaluation of Back Surface Quality]

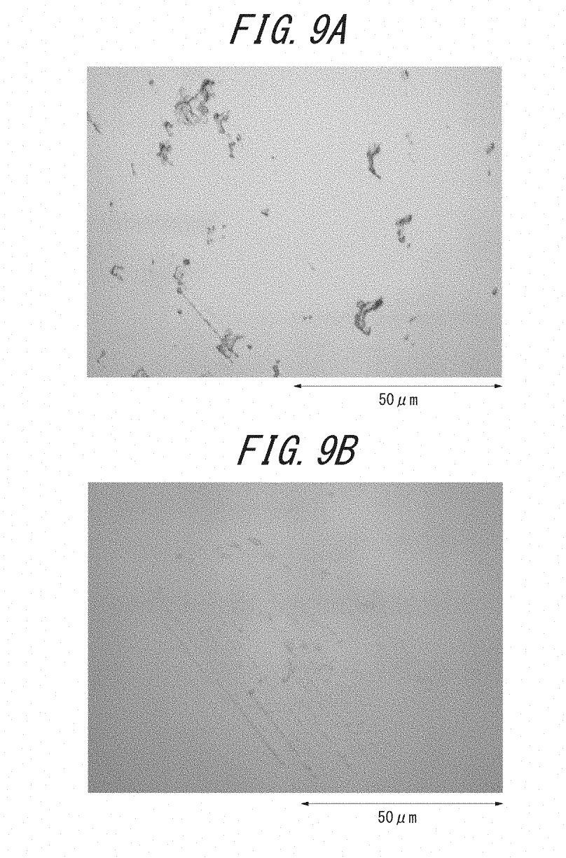

Each of the epitaxial wafers produced in Examples and Conventional Example was subject to observation of the back surface region corresponding to the position of supporting members, which are lift pins in Conventional Example and arc-shaped members in Example, using a confocal laser microscope with a magnification of 1000×. The results are illustrated in FIGS. 9A and 9B. As clear from FIG. 9A, many scratches presumably due to contact with the lift pins were observed in Conventional Example. When the depth or Peak-Valley value was measured for all the scratches in this field, majority of the scratches had a depth more than 0.5 μm. On the contrary, as clear from FIG. 9B, scratches were barely observed in Example, and when the depth of slight roughness observed in this field was measured, all the values were not more than 0.5 μm. In other words, deep scratches having a depth more than 0.5 μm were not observed at all in Example.

Additionally, scratches having a depth more than 0.5 μm were also not observed in the beveled part of the epitaxial wafer in Example. Moreover, when the central part of the back surface was observed using the laser microscope, scratches having a depth or Peak-Valley as small as 0.3 μm or less were also not observed in the epitaxial wafer of Example. Thereby, occurrence of slip dislocation in the epitaxial wafer central part can be certainly prevented.

Furthermore, the epitaxial wafers produced in Example and Comparative Example were subject to observation of the back surface region corresponding to the position of lift pins using a surface examination device, manufactured by KLA-Tencor: Surfscan SP-2, in DCO mode, and measurement of the area of the region having a scattering strength not lower than the value set for laser reflection, or pin mark strength, to evaluate scratches on the epitaxial wafer back surface attributable to lift pins. The result was 0 mm², and no scratches on the epitaxial wafer back surface attributable to lift pins were observed for both Comparative Example and Example.

[Evaluation of Number of Defects in Epitaxial Wafer]

10 epitaxial wafers produced in each of Example and Comparative Example were subject to observation of the epitaxial film using a surface examination device, manufactured by KLA-Tencor: Surfscan SP-2, in DCO mode or Dark Field Composite Oblique mode, to count the number of LPDs or Light Point Defects having a diameter not less than 0.25 μm. From this measurement result, the particle generation status due to dust generation can be evaluated. While the result was 20.1 defects per wafer with a standard deviation of 9.1 in Comparative Example, the value decreased to 6.4 defects per wafer with a standard deviation of 3.7 in Example. This suggests that dust generation from the susceptor could be reduced in Example.

### INDUSTRIAL APPLICABILITY

The susceptor and the epitaxial growth device according to this disclosure, which can prevent occurrence of deep scratches on the wafer back surface and beveled part attributable to contact with lift pins or the susceptor, and reduce dust generation from the susceptor, can preferably be applied to epitaxial wafer production.

### REFERENCE SIGNS LIST

100 Epitaxial growth device

10 Chamber

11 Upper dome

12 Lower dome

13 Dome mounting body

14 Heat lamp

15 Gas supply opening

16 Gas exhaust opening

20 Susceptor

21 Counterbore part

30 Susceptor main body

31A, 31B Recessed part

32 Front surface outer circumferential part of susceptor main body

32A Wafer supporting surface

32B Vertical wall surface

33 Front surface central part of susceptor main body

34A, 34B Bottom surface of recessed part

35 Penetration hole

40A, 40B Arc-shaped member

41A, 40B Front surface of arc-shaped member

42A, 42B Back surface of arc-shaped member

43A, 43B Outer circumferential surface of arc-shaped member

44 Lift pin

45A, 45B inner circumferential surface of arc-shaped member

50 Susceptor support shaft

52 Main column

54 Arm

56 Penetration hole

58 Supporting pin

60 Ascending/descending shaft

62 Main column

64 Support column

66 Tip part of support column

70 Wafer conveying blade

72 Wafer supporting part

W Wafer

1. A susceptor for placing a wafer thereon within an epitaxial growth device, wherein
a counterbore part for placing the wafer thereon is formed on a front surface of the susceptor,
the susceptor has a susceptor main body, and two or more arc-shaped members placed on two or more recessed parts provided in an outer circumferential part of a front surface of the susceptor main body,
a bottom surface of the counterbore part is constituted of entire front surfaces of the arc-shaped members, and a part of the front surface of the susceptor main body,
the susceptor main body is provided with two or more penetration holes, for lift pins that support a back surface of the two or more arc-shaped members, and ascend and descend the two or more arc-shaped members, to be inserted therethrough, and
when the wafer is being placed on the counterbore part and when the wafer is carried out of the counterbore part, the entire front surfaces of the arc-shaped members ascended by the lift pins act as a supporting surface for supporting only an outer circumferential part of a back surface of the wafer by surface contact.

2. The susceptor according to claim 1, the number of the arc-shaped members is two, located in substantially line symmetry from a front view.

3. The susceptor according to claim 1, wherein the lift pins are fixed to the arc-shaped members.

4. An epitaxial growth device comprising:
the susceptor according to claim 1; and
an ascending/descending mechanism for ascending and descending the lift pins by supporting a lower end of the lift pins.

5. An epitaxial wafer comprising: a wafer; and an epitaxial layer formed on a surface of the wafer, wherein scratches having a depth more than 0.5 μm are not observed when a back surface and a beveled part of the epitaxial wafer are observed using a laser microscope.

6. The epitaxial wafer according to claim 5, wherein scratches having a depth as small as 0.3 μm or less are not observed when a central part of the back surface of the epitaxial wafer is observed using a laser microscope.
